(19) United States
(12) Patent Application Publication
(10) Pub. No.: US 2015/0147525 A1
(43) Pub. Date: May 28, 2015

(54) METHOD FOR ENHANCING GROWTH OF CARBON NANOTUBES ON SUBSTRATES

(71) Applicant: Government of the United States as Represented by the Secretary of the Air Force, Wright-Patterson AFB, OH (US)

(72) Inventors: Benji Maruyama, Yellow Springs, OH (US); Gordon A. Sargent, Beavercreek, OH (US); Ahmad E. Islam, Beavercreek, OH (US)

(73) Assignee: Government of the United States as Represented by the Secretary of the Air Force, Wright-Patterson AFB, OH (US)

(21) Appl. No.: 14/552,617

(22) Filed: Nov. 25, 2014

Related U.S. Application Data
(60) Provisional application No. 61/909,876, filed on Nov. 27, 2013.

(51) Int. Cl. C23C 16/26; C23C 14/34; C23F 4/04; C23C 14/35; C23C 16/02; C23C 16/04

(52) U.S. Cl. CPC C23C 16/26; C23C 16/0245; C23C 16/0236; C23C 16/0263; C23C 16/0281; C23C 16/042; C23C 16/0272; C23F 4/04; C23C 14/35; C23C 14/3442
USPC 428/141; 427/551; 427/249.1; 427/585; 216/56; 427/552; 204/192.32; 204/192.12; 204/192.34; 204/192.11

(57) ABSTRACT

Methods for enabling or enhancing growth of carbon nanotubes on unconventional substrates. The method includes selecting an inactive substrate, which has surface properties that are not favorable to carbon nanotube growth. A surface of the inactive substrate is treated so as to increase a porosity of the same. CNTs are then grown on the surface having the increased porosity.

Pursuant to 37 C.F.R. §1.78(a)(4), this application claims the benefit of and priority to prior filed co-pending Provisional Application Ser. No. 61/909,876, filed Nov. 27, 2013, the disclosure of which is expressly incorporated herein by reference.

### RIGHTS OF THE GOVERNMENT

The invention described herein may be manufactured and used by or for the Government of the United States for all governmental purposes without the payment of any royalty.

### FIELD OF THE INVENTION

This invention relates generally to the field of carbon nanotubes and, more particularly, to methods of growing carbon nanotubes on substrates.

### BACKGROUND OF THE INVENTION

Carbon nanotubes (“CNTs”) are cylindrical tubes of carbon and are members of the fullerene structural family. CNTs may be a single-walled carbon nanotube (“SWNT”), meaning that the nanotube wall comprises a single, one-atom thick layer of carbon arranged in a honeycomb-shaped crystal lattice, or CNTs may be a multi-walled carbon nanotube (“MWNT”), meaning that the nanotube wall comprises multiple one-atom think layers of carbon arranged in the honeycomb-shaped crystal lattice. The small size and large surface area of CNTs provide resultant materials with a large surface-to-volume ratio and low density. Due to this unique structure, CNTs possess many desirable properties, including high electrical, high thermal conductivity, high tensile strength, high stiffness, and particular optical properties (controllable bandgap). These properties enable the use of CNTs in a variety of fields and applications, including ultra-lightweight composites, aircraft, spacecraft electrical cables, energy storage, high speed electronics, and bio/chemical sensors.

Realization of these applications requires large-scale production of CNTs with control of chirality, placement, purity, density, and amount during production. While many of the specific mechanisms and parameters of CNT nucleation and growth are still poorly defined, it is known that CNTs may be grown on metal nanoparticle catalysts, such as those comprising iron, cobalt, or nickel, with the size of the metal nanoparticles dictating CNT diameter. However, the nucleation efficiency of the catalytic metal nanoparticles is extremely low (generally, less than about 0.01%), and the reaction conditions and parameters (water concentration, carbon feed, sample placement, etc.) must be precisely controlled to improve CNT growth.

Conventionally, the best CNT growth has been achieved using limited types of “active” catalyst support materials (e.g., alumina or silica) that are comparatively more active than other support materials (e.g., nickel-titanium, graphite). For example, while pristine sapphire (Al₂O₃) does not support nanotube growth, alumina (AlOₓ) deposited by magnetron sputtering, electron beam evaporation, or atomic layer deposition (“ALD”) produces high levels of nanotube nucleation and supports vertically aligned CNT growth.

Investigations have also demonstrated that uniformity (or the lack thereof) of a substrate surface (with or without a metal catalyst) produces aligned and patterned CNTs. For example, removal of material from the substrate surface to create a specific pattern (such as grooves or trenches) provides shape-specific nucleation sites for the CNTs. Many parameters, including the density, placement, and length of the CNTs may be controlled by altering width, depth, number, etc. of the grooves or trenches.

Substrate surfaces having metal catalysts thereon are prone to Ostwald ripening, wherein metallic particles comprising the catalyst dissolve and redeposit into larger crystals or sol particles. Often, catalyst particles are known to diffuse into the substrate material, which terminates growth of the CNT.

Therefore, a need exists in the art that allows the fabrication of a catalyst support with a controllable level of porosity and a reduction of Ostwald ripening.

### SUMMARY OF THE INVENTION

The present invention overcomes the foregoing problems and other shortcomings, drawbacks, and challenges of enabling or enhancing growth of CNTs on substrates conventionally considered to not favor such growth. While the invention will be described in connection with certain embodiments, it will be understood that the invention is not limited to these embodiments. To the contrary, this invention includes all alternatives, modifications, and equivalents as may be included within the spirit and scope of the present invention.

According to an embodiment of the present invention, a method of enhancing growth of carbon nanotubes on substrates includes selecting an inactive substrate, which has surface properties that are not favorable to carbon nanotube growth. A surface of the inactive substrate is treated so as to increase a porosity of the same. CNTs are then grown on the surface having the increased porosity.

Other embodiments of the present invention are directed to a method for enabling or enhancing growth of carbon nanotubes on an inactive substrate and include selecting an inactive substrate having an ordered, crystalline structure. A surface of the inactive substrate is bombarded with high energy ions or high energy particles so as to disrupt the crystalline structure of the surface. CNTs are then grown on the surface having the disrupted crystalline structure.

Still other embodiments of the present invention include a carbon nanotube support material. The carbon nanotube support material includes a substrate having an ordered, crystalline structure. A surface of the substrate has disruptions to the ordered, crystalline structure. The surface having the disruptions is configured to support carbon nanotube growth.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a flowchart of a method of enabling or enhancing CNT growth on a substrate in accordance with embodiments of the present invention.

FIGS. 2A and 2B are sequential, schematic representations of a substrate, in cross-section, processed in accordance with the method of FIG. 1.

FIG. 3 is an enlarged view of the encircled portion of FIG. 2A, illustrating damage on a surface of the substrate of FIGS. 2A and 2B.

FIG. 4 is a graphical representation of an x-ray reflection analysis illustrating exposure time dependency of depth and atomic density of damage on the surface of a substrate processed in accordance with the method of FIG. 1.

FIG. 5 is a graphical representation of time dependent depth and density of damage on a surface of the substrate processed in accordance with the method of FIG. 1.

FIGS. 6A and 6B are graphical representations of an x-ray photoelectron spectroscopy analysis showing surface properties of sapphire substrates processed in accordance with the method of FIG. 1.

FIGS. 7A-7C are graphical representations of x-ray photoelectron spectroscopy analysis showing surface properties of sapphire substrates processed in accordance with the method of FIG. 1.

FIG. 8A is an atomic force microscopy image of the surface of a substrate processed in accordance with the method of FIG. 1.

FIG. 8B is an atomic force microscopy image of the surface of an untreated substrate.

FIGS. 9A and 9B are SEM images, at two different resolutions, of CNTs grown on the surface of the sapphire substrate of FIG. 8A.

FIGS. 10A and 10B are SEM images, at two different resolutions, of CNTs growth on the surface of the untreated substrate of FIG. 8B.

FIG. 11 is an SEM image of a substrate processed in accordance with the method of claim 1, wherein the substrate is masked while treated to increase porosity of its surface.

FIG. 12 is an enlarged SEM image of the substrate of FIG. 11, in a direction orthogonal to a direction of CNT growth.

FIG. 13 is a graphical representation of CNT height with respect to an accelerating voltage of ions during the treatment of a substrate in accordance with the method of FIG. 1.

FIG. 14 is a graphical representation of the data of FIG. 13, normalized for damage dosage.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

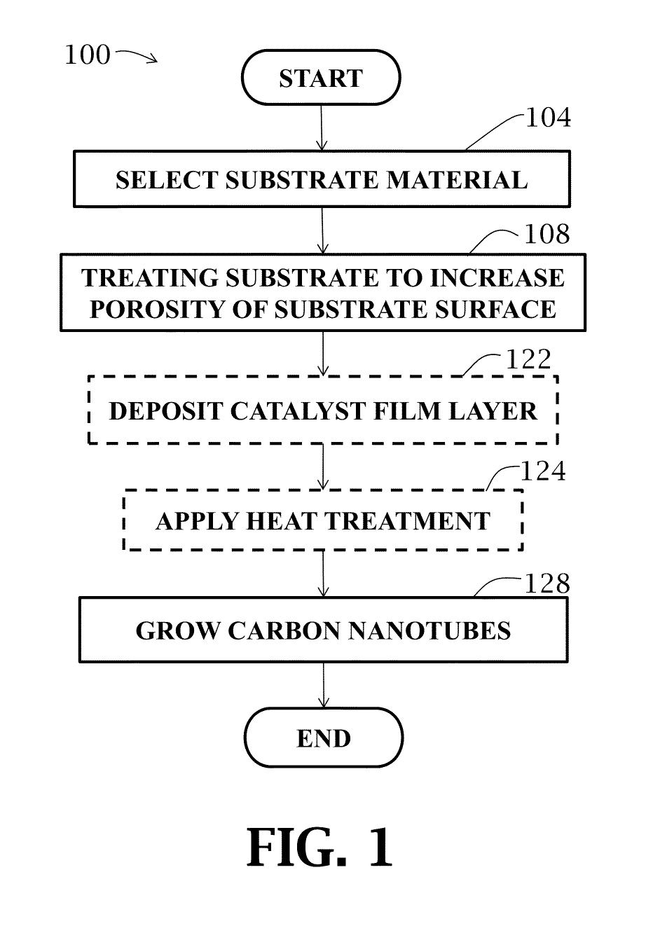

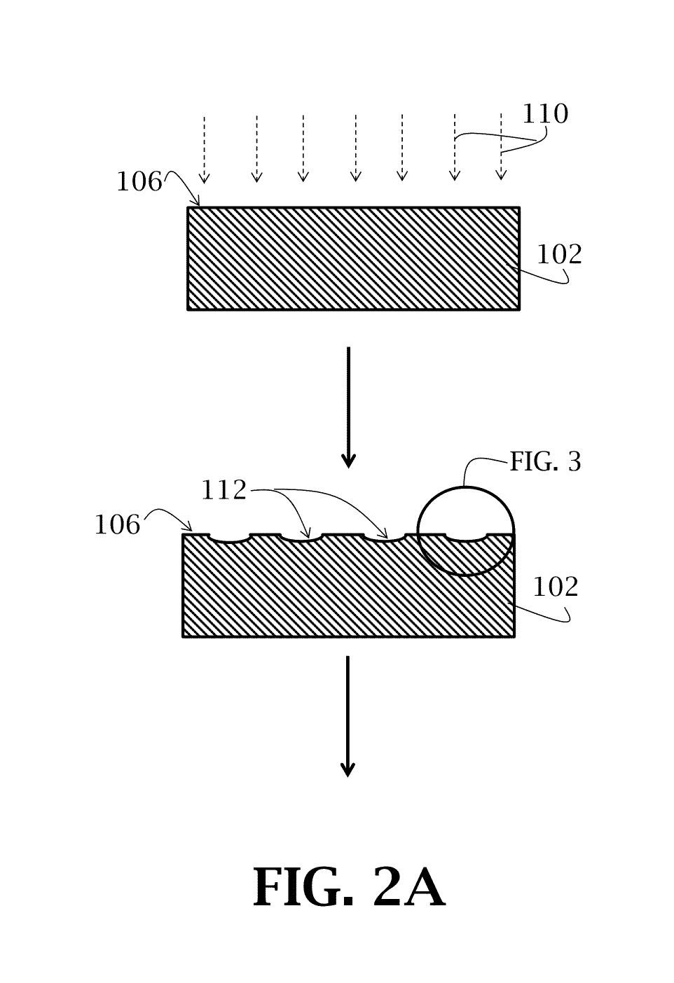

With reference now to the figures, and in particular to FIGS. 1, 2A, and 2B, a method 100 of enhancing CNT growth according to an embodiment of the present invention is described. At start, an inactive support material (hereafter, a substrate 102) is selected (Block 104). The substrate 102 may be one of a large variety of inactive materials, which may be defined as materials that normally do not allow CNT growth or are considered to be poor substrates for CNT growth. In general, a surface 106 of the substrate is an ordered, crystalline structure. For example, silica and silicon-containing materials (such as silicon wafers, quartz, thermal silica, and silicon carbide (SiC)) are suitable inactive materials that generally do not support CNT growth. Other substrates 102 may comprise a wide variety of materials, including, for example, titanium nitride (TiN), zirconia, or various forms of aluminum oxide (such as sapphire and alumina). Some materials suitable for the substrate 102 may be classified as insulators or dielectric materials. Yet, according to some embodiments may include substrates 102 comprising metals capable of forming oxides, such as steel and manganese, as well as dielectric materials or insulators (comprising sapphire and quartz) that are routinely used in electronic devices.

Following selection of material for the substrate 102, a surface 106 of the substrate 102 may be treated with high energy ions or particles, such as by a dry etching process, to obtain a desired degree of porosity of the surface 106 of the substrate 102 (Block 108). In that regard, the dry etch process is controlled to achieve a desired amount of the porosity, a depth of the porosity, or both.

Generally, control of the treatment may be achieved with ions or particles (illustrated as arrow 110) that are sufficiently energetic to alter the microstructure of the surface 106 of the substrate 108 and form regions of damage 112 (also referred to as pores). According to some embodiments, increasing the porosity may include the use of an ion beam bombardment process or a sputtering etch method. A focused ion beam instrument, such as an ion gun, may be used to generate a focused beam of energetic ions having well-controlled and well-defined ion composition and energy distribution. A variety of ion sources may be used, including one or more inert or noble gases such as argon, helium, krypton, and xenon. If desired, reactive gases (such as hydrogen, oxygen, sulfur, and water) may be included to facilitate non-equilibrium chemistries. For example, use of hydrogen gas bombardment on an alumina-based substrate may produce a hydrated alumina. Alternatively, use of hydrogen/argon gas bombardment on a metal film deposited on an alumina-based substrate may drive metal atoms into the catalyst support (ion beam mixing). Both of these techniques should form a catalytically-active support and growth surface.

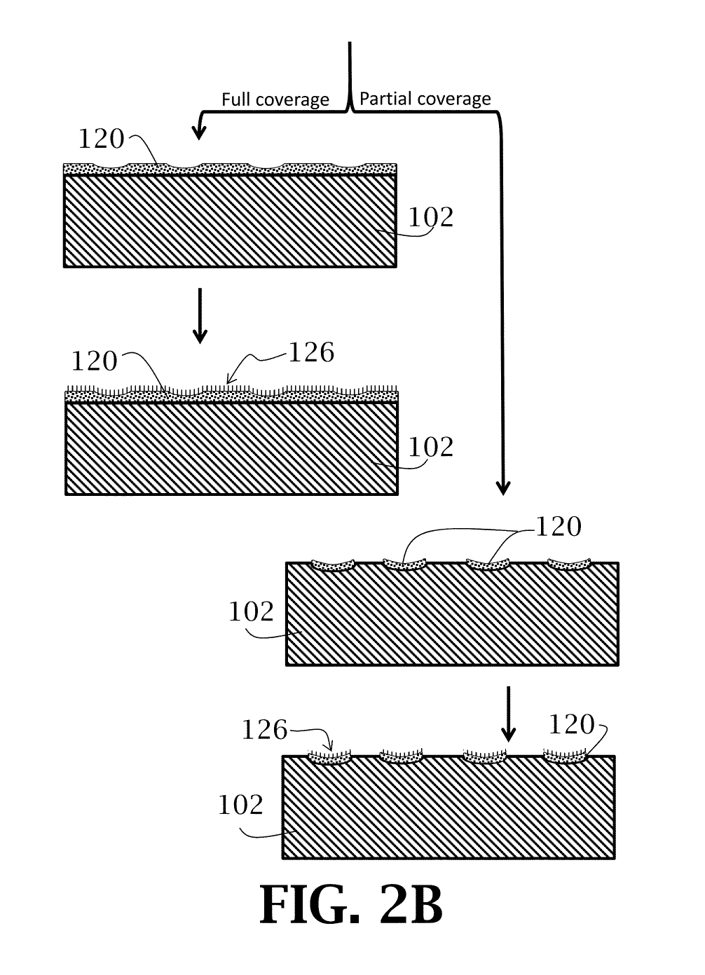

With momentary reference now to FIG. 3, ion beam bombardment may result the damage 112 having two layers: an amorphous, upper layer 114 and a low-density crystalline, lower layer 116. An interfacial region (illustrated as a dashed line 118) between the upper and lower layers 114, 116 is lower in density than either of the upper and lower layers 114, 116. The damage from the ion beam is believed to alter the chemical bonding in the material comprising the substrate 102 to produce dangling bonds, active sites, vacancies, interstitial sites, or combinations thereof in this interfacial region 118.

According to other embodiments of the present invention, treating the substrate surface 106 may include plasma or reactive ion etch processes. Plasma or ion etching may be generated using direct current or radio-frequency electrical pulses to ignite the plasma or activate the reactive ions. In such processes, temperature, pressure, or both may be used to control etch parameters, such as the ion density, damage rate, and amount of material etched away.

Referring now to FIGS. 1 and 2B, and following treatment (Block 108), the substrate surface 106 having damage 112 thereon may, optionally, be treated for deposition of a catalyst film 120 (Block 122). In that regard, the catalyst film 120 may be deposited onto the surface 106 of the substrate 102, generally, so as to substantially cover the surface 106 (“Full coverage” branch of FIG. 2B). Alternatively, the catalyst film 120 may be deposited onto the damage 112 of the surface 106 (“Partial coverage” branch of FIG. 2B). Catalyst films 120 may comprise suitable metal materials, including transition metals (such as iron, nickel, cobalt, and alloys thereof) or organometallic compounds having transition metals (such as ferrocene). Catalyst films 120 may additionally or alternatively comprise non-metal catalysts, such as zirconia, germanium, and silicon dioxide.

Generally, the material comprising the catalyst film 120 may be deposited on the surface 106 of the substrate 102 using conventional deposition technique, such as magnetron/ion beam sputtering, e-beam evaporation, or ALD. Alternatively, catalyst nanoparticles suspended in a liquid such as water or a saline solution may be drop-casted onto the desired location(s) on the catalyst support surface, followed by drying to generate a layer of catalyst nanoparticles. In yet further embodiments, the catalyst layer may be generated by bombarding the catalyst support surface with metal ions, such as from an ion gun.

Additionally, or alternatively, still, the surface 106 of the substrate 102 having damage 112, with or without the catalyst film 120, the substrate 102 may, optionally, be heat treated (Block 124) to recrystallize the damage 112 such that the surface 106 is roughened but is epitaxially-extended from the substrate 102. More particularly, the treatment to increase porosity of the substrate surface 106 generates damage 112 that is disordered, amorphous, and roughened. The increased roughness associated with the damage 112 enhances CNT growth, locally; however, this localized, enhanced CNT growth reduces uniformity of CNT alignment, chirality, or both. By applying a heat-treatment, the areas of damage 112 partially recrystallize and, thereby achieve a more ordered structure without losing the desired level of porosity, presences of dangling bonds, etc., which are desirable for CNT growth. Resultantly, CNT growth may be enhanced while alignment, orientation, and chirality may be controlled and maintained.

With or without the catalyst film, heat treatment, or both, growth of CNTs 126 may initiated (Block 128) by subjecting the substrate 102 to reaction conditions that are favorable to growth of CNTs. For example, the surface 106, having damage 112 thereon, is exposed to an elevated temperature (from about 500° C. to about 1000° C.) a flow of gas comprising a carbon-containing gas, such as methane (CH₄), ethylene (C₂H₄), and acetylene (C₂H₂). Typically, the flow of gas will include a carrier gas argon and helium or additive gases, like hydrogen, for reduction of catalyst film 120. Alternatively, the surface 106, having the damage 112 thereon, may be exposed to a liquid injection of a carbon source, such as vapors of ethanol (C₂H₅OH), methanol (CH₃OH), isopropanol (C₃H₇OH), xylene (C₆H₄(CH₃)₂), and toluene (C₆H₅CH₃). Exposing the surface 106 to the carbon-containing gas or carbon source continues for a period of time until CNTs having a desired length result.

As substantially described herein, the present invention includes a novel process of transforming a substrate into a highly active catalyst support. Instead of depositing or adding materials favorable as a catalyst support, ion beam bombardment is used to disrupt a structure (physical, chemical, or both) of a surface of the substrate. The contrast between CNT growth on ion beam bombarded substrates and the lack thereof growth on pristine substrates underlines the sharp difference in catalyst dynamics between an atomically perfect surface and an intentionally disrupted surface.

The following examples and methods are presented as illustrative of the present invention or methods of carrying out the invention, and are not restrictive or limiting of the scope of the invention in any manner.

### Example 1

An alumina substrate (density ranging from about 2.9 g/mL to about 3.1 g/mL) was dosed with

$$2.4 \times {10}^{17} \frac{{Ar}^{+} ions}{{cm}^{2} sec}$$

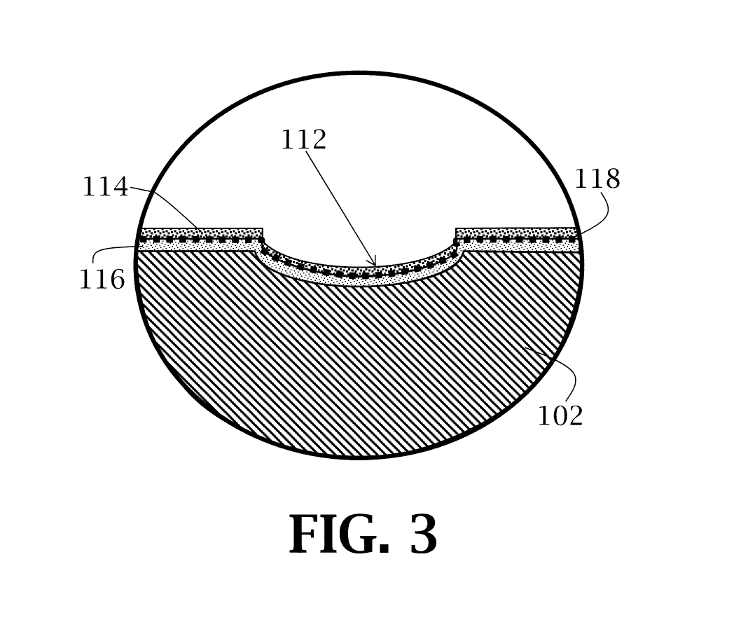

a voltage of 5 KeV for varying amounts of time. FIG. 4 is a graphical representation of X-ray reflection (“XRR”) studies illustrating exposure time effects. The Y-axis is intensity of reflected x-rays; the X-axis is angle of incidence.

TABLE 1

| Line style | Exposure time (mm) |
|---|---|
| | 0.33 |
| [symbol] | 1.00 |
| [symbol] | 5.00 |
| [symbol] | 10.00 |
| [symbol] | 14.33 |

The depth and atomic density of the resultant damaged layer varied in proportion to exposure time. A similar level of control may be achieved by altering acceleration voltage of the Ar⁺ ions (data not shown).

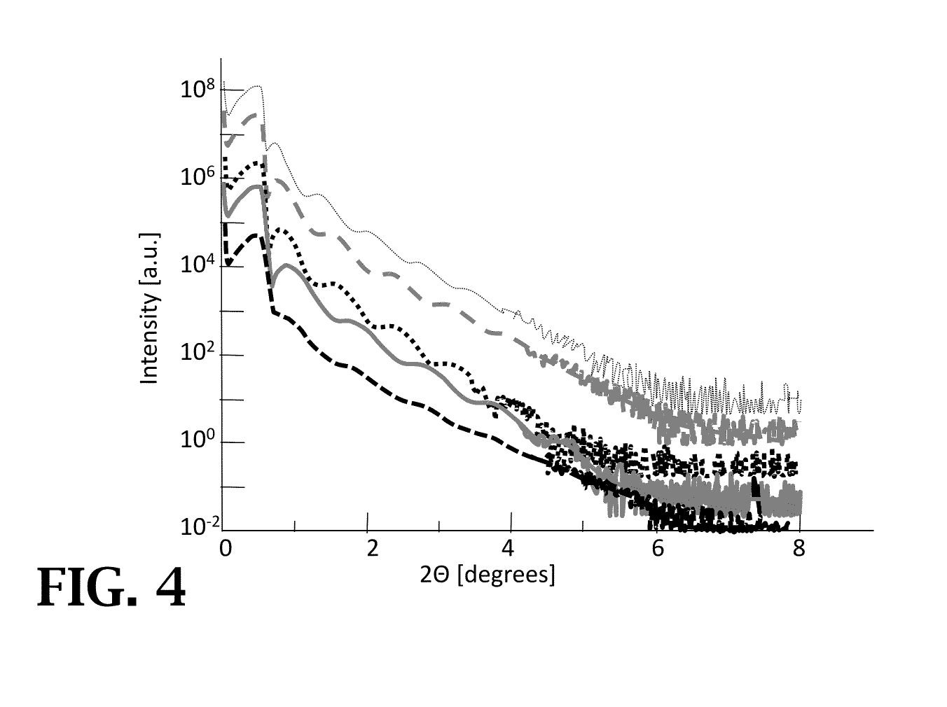

FIG. 5 is a graphical representation of a relationship between damage depth (line with triangles; left Y-axis) and density of the damage (line with squares; right Y-axis) with respect to time. Like the exposure time dependent damage illustrated in FIG. 4, as damage depth and duration increase, the density of the damaged also increases.

As shown, the thickness (or depth) of the damaged should be maintained above a certain threshold, which is generally about 10 nm. Some recrystallization of the damaged may occur during CNT growth, and if the thickness of the damaged layer drops below about 10 nm, no nanotube growth occurs (data not shown).

### Example 2

To generate catalyst supports with a desired level and thickness of porosity, crystalline sapphire (both c-cut and a-cut) and quartz (X-, Y-, and ST-cut) substrates were bombarded with 1.5-6 keV argon (Ar⁺) or helium (He⁺) ions at varying ion densities (ranging from about 1.4×10¹⁹/cm² to about 2.1×10²⁰/cm²) from an ion gun (Mode: IBS/e, South Bay Technology, Inc., Sam Clemente, Calif.) (hereafter referred to as ion-beam damaged (“IBD”) substrates). A thin film (ranging from 0.5 nm to about 3 nm) of iron was deposited on the IBD substrates using another ion gun of the IBS/e system configured in deposition mode.

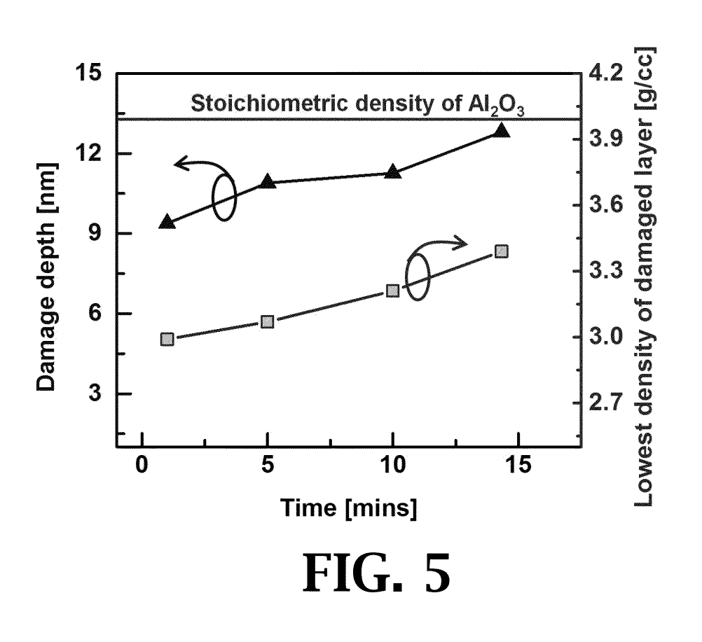

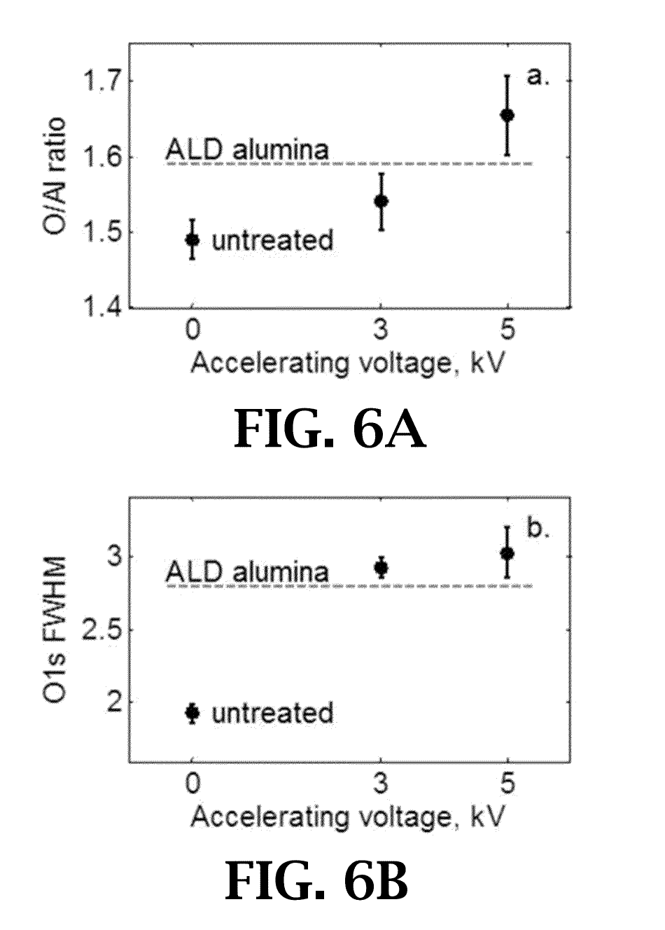

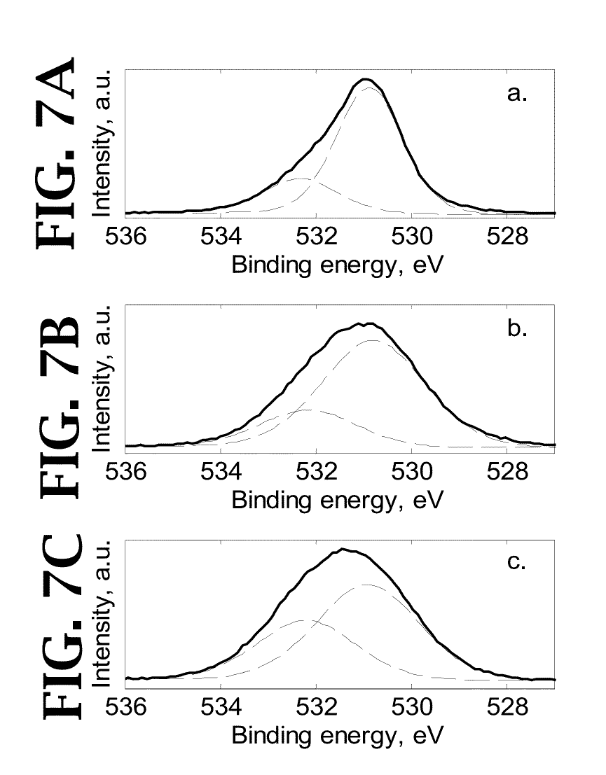

The degree of porosity and thickness of damage under various conditions have been characterized using XRR and cross-sectional transmission electron microscopy (X-TEM) (data not shown). Surface properties of each substrate were characterized using x-ray photoelectron spectroscopy (“XPS”) and are shown (for sapphire substrate) in FIGS. 6A-7C. The XPS analysis of FIGS. 6A-7C support a conclusion that ion beam-treated surfaces are non-stoichiometric (O vs. Al atoms) and have an abundance of hydroxyl (OH−) groups like ALD alumina. The observed increase in both the O/Al atomic ratio (FIG. 6A) and the O 1s peak width (FIG. 6B), referred to as Full-Width at Half Maximum (“FWHM”), upon Ar⁺ ion bombardment at increasing accelerating voltage as compared to untreated sapphire corresponds to hydroxyl enrichment of the sapphire surface. FIGS. 7A-7C shows how XPS data, obtained using a Surface Science Instrument (“SSI”) M-probe equipped with an Al Kα X-ray source (operated at about 4×10⁻⁷ Pa base pressure) are decomposed into Al- and H-bound peaks at around about 531 eV and about 532.5 eV, using CasaXPS software obtained from Casa Software Ltd. Shirley background subtraction was performed during XPS analysis. FIGS. 8A and 8B are atomic force microscopy images of the untreated sapphire substrate surface and the sapphire substrate surface following ion beam damage, respectively, at approximately 6 KeV with Ar⁺ ions at a density of 1.4×10¹⁹/cm². A comparison of FIG. 8B to FIG. 8A suggests a significant change in the topography of the surface induced via the ion bombardment.

The increase in hydroxyl enrichment, shown in FIG. 6A, correlates to higher activity and longer lifetime of the Fe catalyst supported on the sapphire surface. FIGS. 6A and 6B also demonstrate that the O/Al ratio and O is FWHM are close to (at an accelerating voltage of 3 kV and ion energy of 3 keV) or exceed (at an accelerating voltage of 5 kV and ion energy of 5 keV) values obtained for ALD alumina (represented by the horizontal, dotted lines). This suggests that Ar⁺ ion bombardment makes the sapphire surface non-stoichiometric, enriched in hydroxyl groups, and introduces disorder needed to enhance catalyst activity and lifetime. This bombardment also obviates the need to deposit alumina layers.

### Example 3

The iron-coated samples of Example 2 were then inserted into a CNT growth chamber and subjected to the following growth conditions: 585° C. hydrogen anneal for 10 min at a flow rate of 300 sccm, rapid cooling in hydrogen/argon ambient, and then CNT growth at 760° C. for 30 min at a flow rate of 470 sccm, 100 sccm, and 25 sccm for argon, hydrogen, and ethylene, respectively.

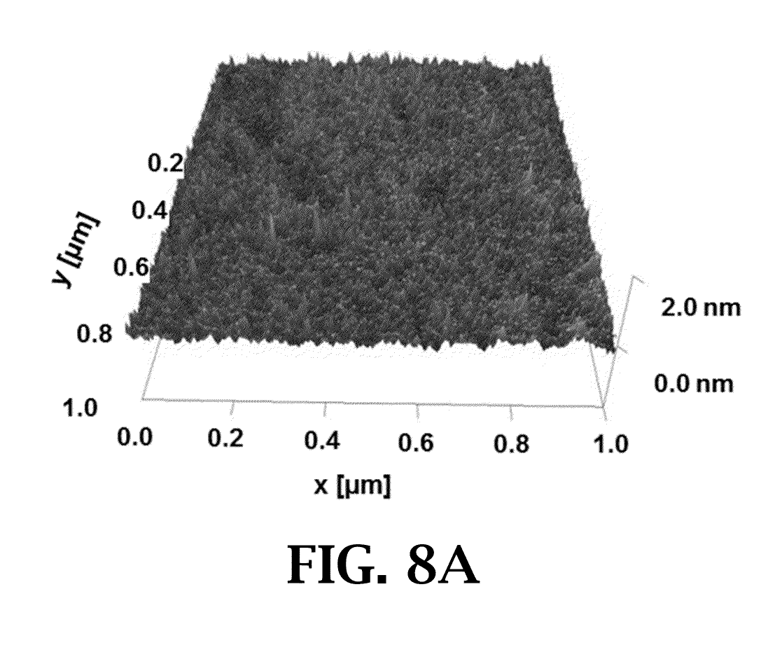

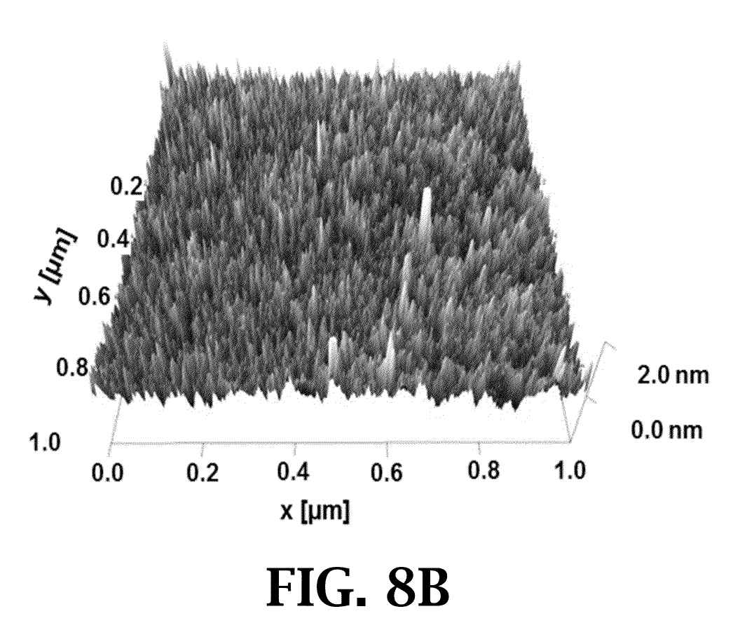

FIGS. 9A-10B are SEM images demonstrating a difference between CNT growth on a substrate surface having damage (sapphire substrate subjected to ion beam bombardment) and a pristine substrate surface (sapphire substrate with atomically perfect surface structures). As shown in FIGS. 9A and 9B, substrate surface having damage, such as was generated in Example 2, grew tall carpets of vertically-aligned CNTs with heights of approximately 800 μm. The scale bar is 200 μm in FIGS. 9A and 2 μm in FIG. 9B. The height of the CNTs of FIGS. 9A and 9B is approximately equivalent to the height of CNTs formed using atomic-layer or sputter deposited AlOₓ supports.

By comparison, the pristine sapphire sample of FIGS. 10A and 10B, subjected to the same conditions as those imaged in FIGS. 9A and 9B, did not grow CNTs. The scale bar is 1 μm in FIGS. 10A and 100 nm in FIG. 10B. This striking transformation of sapphire from an inactive catalyst support in FIGS. 10A and 10B to a highly active support in FIGS. 9A and 9B supports viability of CNT growth, on levels nearly equivalent to ALD or sputter-deposited alumina, according to the present invention.

### Example 4

Methods according to embodiments of the present invention may be used to pattern CNT growth by controlling a pattern of the treatment by ion bombardment. Sapphire substrates, similar to those used in Example 1, were masked with metal grids, in this case a transmitting electron microscope (“TEM”) grid, and then treated via ion bombardment. The TEM grid was removed and an iron catalyst deposited onto the damaged substrate. Deposition of the iron catalyst was not masked such that both the damage and the pristine portions of the surface of the substrate were uniformly coated with iron catalyst.

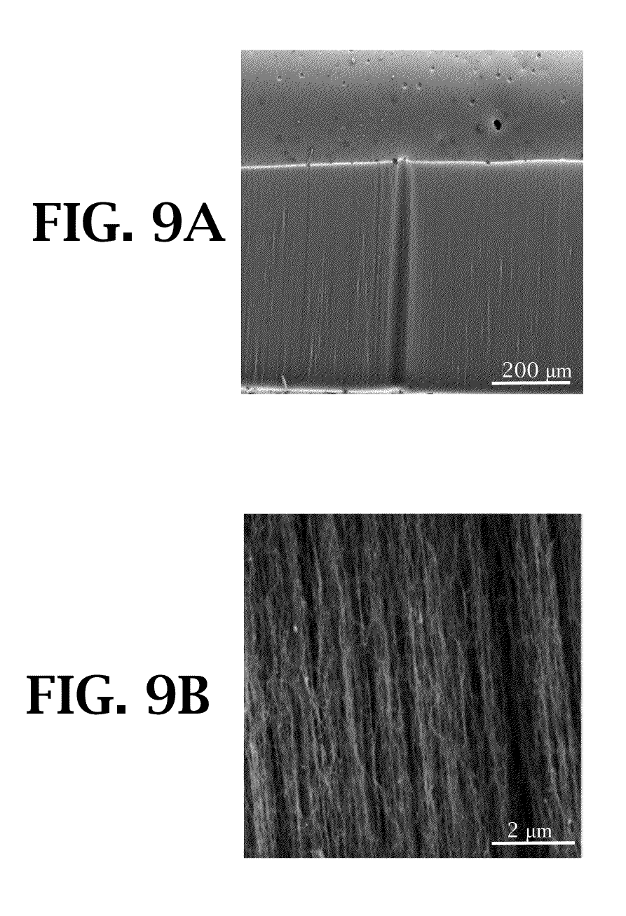

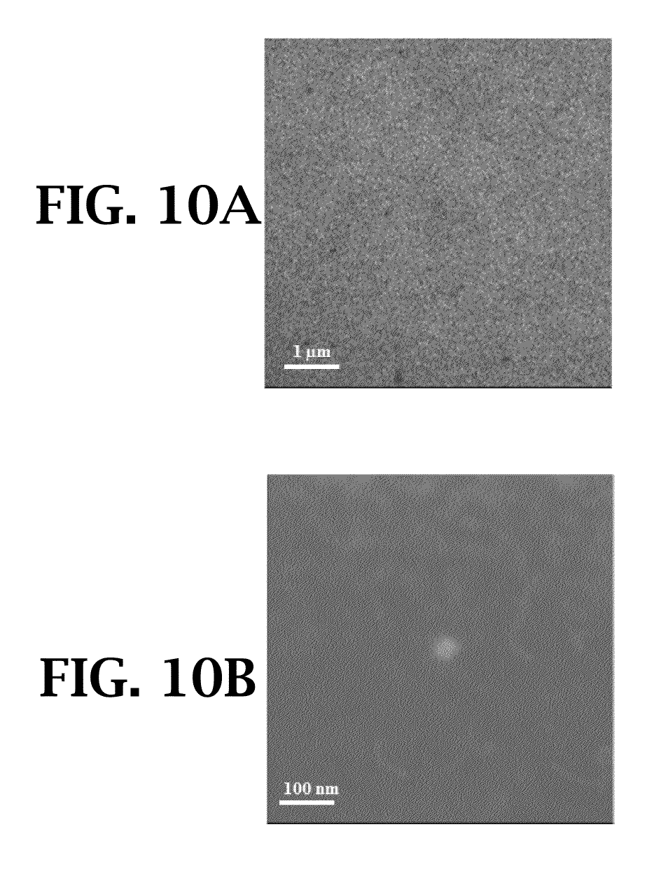

FIG. 11 is a low resolution SEM image, scale bar is 100 μm, and FIG. 12 is a high resolution SEM image, scale bar is 4 μm, of vertically-aligned CNTs grown via a masked ion beam bombardment. As can be seen in these figures, despite a uniform iron catalyst coating, large numbers of vertically-aligned CNTS grew on portions of the substrate having damage. CNT growth in the pristine regions, coated with iron catalyst, was either sparse or non-existent. The difference between the masked vs. unmasked areas (damage vs. pristine) is further confirmation of an activation effect as damage and pristine regions were adjacent to one another on the same substrate. It also demonstrates a unique advantage to ion beam-induced damage activation, where migration of the iron catalyst is controlled by engineering the substrate rather than by controlling deposition of the iron catalyst. Not only can inactive materials be converted to active materials for CNT growth, but this conversion can be done in a controlled manner so as to develop a catalyst support with exact properties.

### Example 5

In addition to spatial patterning of ion beam activation, depth and degree of damage to the substrate may be altered by controlling the ion beam processing parameters.

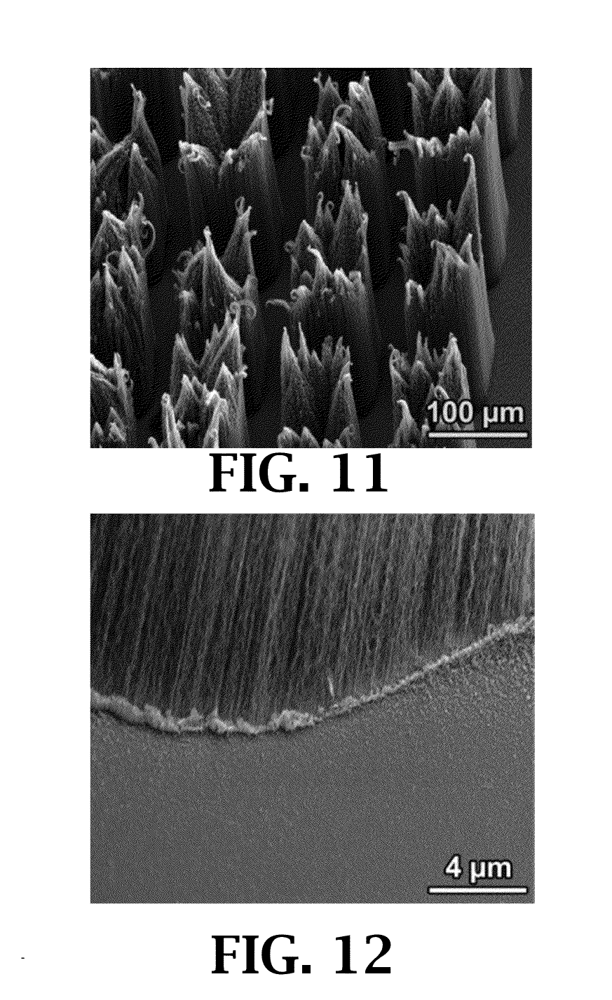

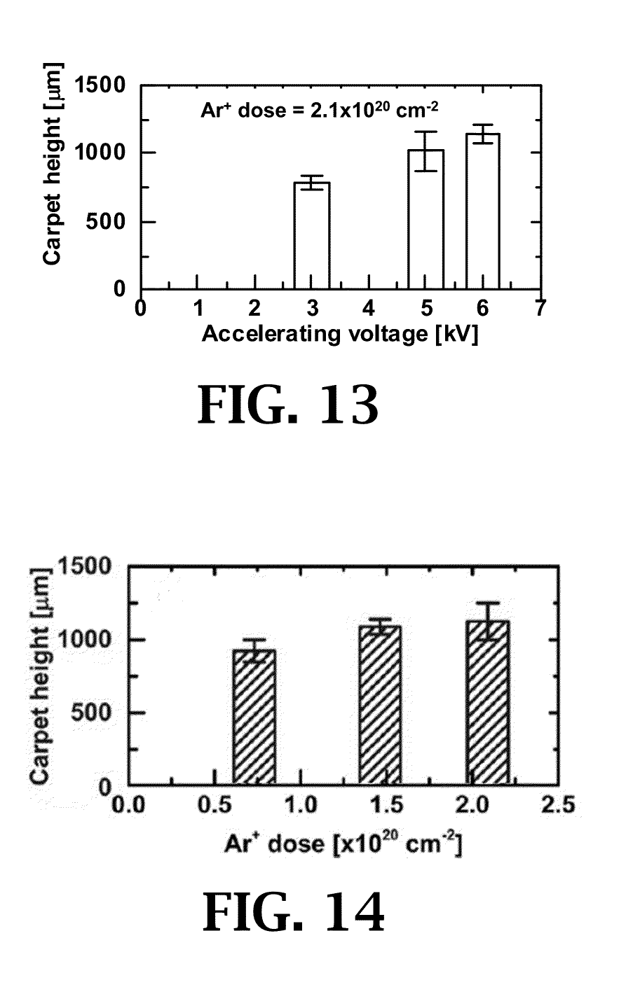

Sapphire substrates were bombarded with ion beams, as was described in Example 1, except that the ion beam accelerating voltage was varied at a fixed Ar⁺ ion dose (see FIG. 13) and the Ar⁺ ion dose was varied at a fixed acceleration voltage (see FIG. 14). Treated substrates were then are coated with approximately 1 nm Fe catalyst film and annealed in hydrogen ambient at 585° C. for 10 min Annealing induced de-wetting of the film that via coarsening and subsurface diffusion into the porous catalyst support, forms iron nanoparticles on top of activated surface.

In FIG. 13, the Ar⁺ ion dose was normalized with respect to its value at 2.1×10²⁰/cm². It is evident from these figures that increased intensity in ion beam processing via increased acceleration voltage or damage dose led to a more active catalyst support and thus taller nanotube carpets. That is, nanoparticles formed at lower degrees of ion beam damage are large and isolated, while those formed at higher degrees of ion beam damage are denser and smaller (data not shown). Consequently, substrates prepared with the higher degrees of ion beam damage had reduced surface roughness and higher particle density, both of which are favorable to high catalyst activity. AFM analysis, therefore, confirms the presence of greater catalytic activity, more sub-surface diffusion, and less Ostwald ripening with a higher degree of ion beam damage, which may be accomplished by increasing the damage dose and/or the acceleration voltage.

The present invention includes methods for enabling or enhancing growth of CNTs on substrates, such as sapphire, that, without treatment, are conventionally considered to be poor substrates for such growth. By treating at least a portion of the substrate with high energy particles, damage and disruptions are made in a surface of the substrate. As such, the ordered crystal structure of a so-called inactive substrate is changed to a so-called active substrate having a surface that exhibits a disordered or amorphous structure. This damage is porous and supports controllable, highly-aligned CNT growth. A thin catalyst film may be deposited onto the damage to further enhance nanotube growth. Although some embodiments of the presently disclosed method may not include deposition of the catalyst film, the substrate or substrate surface may be referred as a “catalyst support” configured to enable or enhance CNT growth.

By carefully controlling and tuning a variety of processing variables, such as exposure time, particle or ion type, particle or ion concentration, accelerating voltage, current over time, and beam fluence, a degree of porosity (or an amount of damage) and a depth of the damage to the substrate (or a thickness of the catalyst support) may be controlled. This in turn may be used to precisely control one or more of location, density, and orientation of CNTs grown on the substrate. Embodiments of the present invention may be useful in a variety of fields and applications, including, for example, electronic devices (digital, radio frequency, and power electronics), transparent electrodes and conductors, photovoltaics, and sensors. Embodiments of the present invention may also be useful for modifying fiber-matrix interfaces in composite materials.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A method for enabling or enhancing growth of carbon nanotubes (CNTs) on an inactive substrate, the method comprising:
selecting the inactive substrate, the inactive substrate having surface properties not favorable to CNT growth;
treating a surface of the inactive substrate to increase a porosity thereof; and
growing CNTs on the surface of the inactive substrate having the increased porosity.

2. The method of claim 1, wherein treating the surface comprises bombarding the surface with high energy ions or high energy particles.

3. The method of claim 2, wherein bombarding the surface includes an ion beam bombardment process, a sputtering etch process, an ion gun process, a plasma etch process, an ion etch process, or a reactive ion etch process.

4. The method of claim 1, wherein treating the surface comprises a dry etch process.

5. The method of claim 1, further comprising:
depositing a catalyst film on the surface having the increased porosity before growing the CNTs.

6. The method of claim 5, further comprising:
annealing the catalyst film before growing the CNTs.

7. The method of claim 5, wherein the catalyst film comprises a transition metal or an organometallic compound.

8. The method of claim 7, wherein the catalyst film comprises the transition metal, which is selected from the group consisting of iron, nickel, cobalt, and alloys thereof.

9. The method of claim 7, wherein the catalyst film comprises the organometallic compound, which is ferrocene.

10. The method of claim 5, wherein the catalyst film is selected from the list consisting of zirconia, germanium, and silicon dioxide.

11. The method of claim 1, wherein depositing the catalyst film includes an ion beam sputtering process, an e-beam evaporation process, an atomic layer deposition process, or a magnetron sputtering process.

12. The method of claim 1, further comprising:
masking the surface of the inactive substrate before treating the surface.

13. A method for enabling or enhancing growth of carbon nanotubes (CNTs) on an inactive substrate, the method comprising:
selecting the inactive substrate having an ordered, crystalline structure;
bombarding a surface of the inactive substrate with high energy ions or high energy particles so as to disrupt the crystalline structure thereof; and
growing CNTs on the surface of the inactive substrate having the disrupted crystalline structure.

14. The method of claim 13, wherein bombarding the surface includes an ion beam bombardment process, a sputtering etch process, an ion gun process, a plasma etch process, an ion etch process, or a reactive ion etch process.

15. The method of claim 13, wherein treating the surface comprises a dry etch process.

16. The method of claim 13, further comprising:
depositing a catalyst film on the surface having the disrupted crystalline structure before growing the CNTs.

17. The method of claim 16, further comprising:
annealing the catalyst film before growing the CNTs.

18. The method of claim 16, wherein depositing the catalyst film includes an ion beam sputtering process, an e-beam evaporation process, an atomic layer deposition process, or a magnetron sputtering process.

19. The method of claim 13, further comprising:
masking the surface of the inactive substrate before treating the surface.

20. The method of claim 13, wherein a degree, a depth, or both of crystalline structure disruption is altered by altering at least one of a bombardment exposure time, a particle type, a particle concentration, an accelerating voltage, a current, and a beam fluence.

21. The method of claim 20, wherein the depth of the disrupted crystalline structure extends at least 10 nm into the inactive substrate from the surface.

22. A carbon nanotube support material comprising:
a substrate having an ordered, crystalline structure; and
a surface of the substrate having disruptions to the ordered, crystalline structure,
wherein the surface having the disruptions is configured to support carbon nanotube growth.

23. The carbon nanotube support material of claim 22, wherein the disruptions further comprise:
an amorphous, upper layer;
a crystalline, lower layer; and
an interfacial region therebetween have a density that is lower than a density of the amorphous, upper layer and a density of the crystalline, lower layer.

24. The carbon nanotube support material of claim 22, further comprising:
a catalyst film layer on the surface having the disruptions.
